(19) United States
(12) Patent Application Publication
(10) Pub. No.: US 2024/0030015 A1
(43) Pub. Date: Jan. 25, 2024

(54) PLASMA PROCESSING APPARATUS AND PLASMA STATE ESTIMATION METHOD

(71) Applicant: TOKYO ELECTRON LIMITED, Tokyo (JP)

(72) Inventor: Eiki KAMATA, Yamanashi (JP)

(21) Appl. No.: 18/353,747

(22) Filed: Jul. 17, 2023

(30) Foreign Application Priority Data
Jul. 21, 2022 (JP) 2022-116096

(51) Int. Cl. H01J 37/32; G05B 15/02

(52) U.S. Cl. CPC H01J 37/3299; G05B 15/02; H01J 2237/24578

(57) ABSTRACT

There is a plasma processing apparatus comprising: a processing container in which a mounting table on which a substrate is mounted is arranged and plasma processing is performed; a plurality of sensors for detecting a state of plasma generated in the processing container; and a controller for estimating a state of plasma in the processing container based on the state of plasma obtained from the plurality of sensors, wherein the controller obtains a two-dimensional distribution representing the state of plasma with respect to installation positions of the plurality of sensors, from data obtained from the plurality of sensors, and estimates the state of plasma in the processing container based on the obtained two-dimensional distribution.

### CROSS-REFERENCE TO RELATED APPLICATIONS

This application claims priority to Japanese Patent Application No. 2022-116096, filed on Jul. 21, 2022, the entire contents of which are incorporated herein by reference.

### TECHNICAL FIELD

The present disclosure relates to a plasma processing apparatus and a plasma state estimation method.

### BACKGROUND

Japanese Laid-open Patent Publication No. 2019-46787 proposed a technology in which a plasma probe is provided on an upper portion of a sidewall in a processing container to measure the state of plasma.

### SUMMARY

The present disclosure provides a technology for estimating the state of plasma in a processing container.

In accordance with an aspect of the present disclosure, there is a plasma processing apparatus comprising: a processing container in which a mounting table on which a substrate is mounted is arranged and plasma processing is performed; a plurality of sensors for detecting a state of plasma generated in the processing container; and a controller for estimating a state of plasma in the processing container based on the state of plasma obtained from the plurality of sensors, wherein the controller obtains a two-dimensional distribution representing the state of plasma with respect to installation positions of the plurality of sensors, from data obtained from the plurality of sensors, and estimates the state of plasma in the processing container based on the obtained two-dimensional distribution.

### BRIEF DESCRIPTION OF THE DRAWINGS

FIG. 1 is a sectional view schematically showing an example of a plasma processing apparatus according to an embodiment.

FIG. 2 is a diagram showing an example of the arrangement of an antenna module on a top wall portion according to an embodiment.

FIG. 3 is a diagram showing an example of two-dimensional distribution representing the state of plasma according to an embodiment.

FIG. 4 is a diagram illustrating the decomposition of the two-dimensional distribution by Zernike polynomials according to an embodiment.

FIG. 5A is a diagram showing an example of the decomposition of the two-dimensional distribution according to an embodiment.

FIG. 5B is a diagram showing an example of the decomposition of the two-dimensional distribution according to an embodiment.

FIG. 6A is a diagram showing an example of two-dimensional distribution according to an embodiment.

FIG. 6B is a diagram showing the component intensity of each term of the Zernike polynomials according to an embodiment.

FIG. 6C is a diagram showing the component intensity of each term of the Zernike polynomials according to an embodiment.

FIG. 7 is a diagram showing an example of two-dimensional distribution according to an embodiment.

FIG. 8 is a diagram illustrating a flow of estimating a plasma state according to an embodiment.

FIG. 9 is a diagram showing a cylindrical space in a processing container according to an embodiment.

FIG. 10 is a diagram illustrating an example of abnormality detection according to an embodiment.

FIG. 11 is a diagram illustrating an example of abnormality detection according to an embodiment.

FIG. 12 is a diagram illustrating an example of specifying the influence of the component intensity of each term of the Zernike polynomials on abnormality according to an embodiment.

FIG. 13 is a flowchart showing an example of a flow of plasma state estimation processing according to an embodiment.

FIG. 14A is a diagram showing an example of the arrangement of sensors according to an embodiment.

FIG. 14B is a diagram showing an example of the arrangement of sensors according to an embodiment.

FIG. 15 is a diagram showing an example of the arrangement of sensors according to an embodiment.

### DETAILED DESCRIPTION

Hereinafter, a plasma processing apparatus and a plasma state estimation method according to an embodiment of the present disclosure will be described in detail with reference to the accompanying drawings. Further, the disclosed plasma processing apparatus and plasma state estimation method are not limited to this embodiment.

However, conventionally, only a plasma state at the installation position of a plasma probe can be detected. Thus, a technology for estimating the plasma state in a processing container, especially the state of plasma directly above a substrate is expected.

### Embodiment

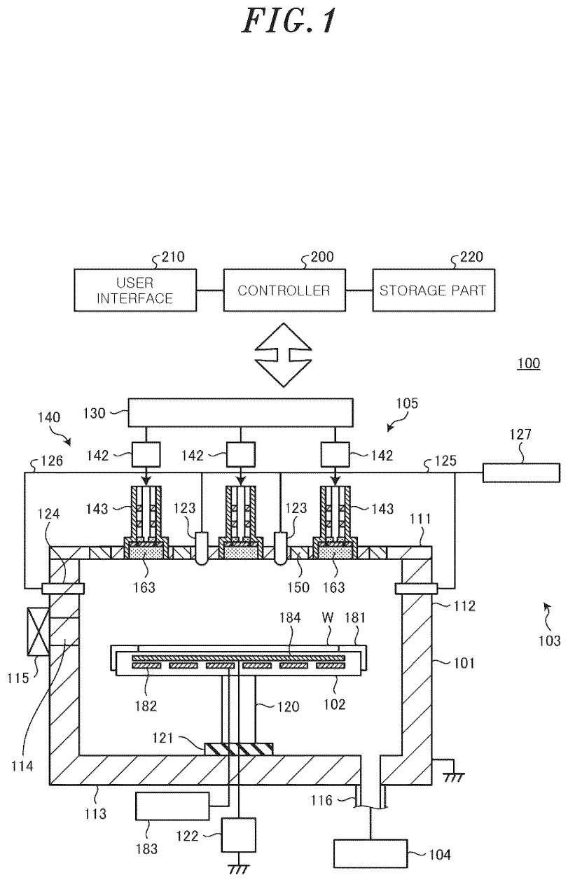

An embodiment will be described. First, an example of a plasma processing apparatus according to the present disclosure will be described. In an embodiment, a case where the plasma processing apparatus of the present disclosure uses a plasma processing apparatus 100 that generates plasma by microwaves will be described as an example. FIG. 1 is a sectional view schematically showing an example of the plasma processing apparatus 100 according to an embodiment. The plasma processing apparatus 100 shown in FIG. 1 includes a processing container 101, a mounting table 102, a gas supply mechanism 103, an exhaust device 104, a microwave introduction device 105, and a controller 200.

The processing container 101 accommodates a substrate W such as a semiconductor wafer. The mounting table 102 is installed in the processing container 101. The substrate W is mounted on the mounting table 102. The gas supply mechanism 103 supplies gas into the processing container 101. The exhaust device 104 exhausts the inside of the processing container 101. The microwave introduction device 105 generates microwaves for generating plasma in the processing container 101, and introduces the microwaves into the processing container 101. The controller 200 controls the operation of each part of the plasma processing apparatus 100.

The processing container 101 is formed of metal material such as aluminum and an alloy thereof, and has a substantially cylindrical shape. The processing container 101 has a plate-shaped top wall portion 111, a bottom wall portion 113, and a sidewall portion 112 connecting the top wall portion and the bottom wall portion. The inner wall of the processing container 101 is coated with a protective film such as yttria (Y₂O₃). The microwave introduction device 105 is installed above the processing container 101, and introduces electromagnetic waves (microwaves) into the processing container 101 to generate plasma. The microwave introduction device 105 will be described below in detail.

The top wall portion 111 has a plurality of openings into which a microwave radiation mechanism 143 and a gas introduction nozzle 123 of the microwave introduction device 105, which will be described later, are fitted. The sidewall portion 112 has a loading/unloading port 114 for loading and unloading the substrate W to or from a transfer chamber (not shown) that is adjacent to the processing container 101. Further, the sidewall portion 112 is provided with a gas introduction nozzle 124 at a position above the mounting table 102. The loading/unloading port 114 is configured to be opened or closed by a gate valve 115.

In the plasma processing apparatus 100 according to an embodiment, a plurality of sensors 150 are installed in the processing container 101. As shown in FIG. 1, the plurality of sensors 150 are installed on the top wall portion 111 that forms the upper surface of the processing container 101. The sensors 150 are concentrically arranged on the lower surface of the top wall portion 111 with a plurality of radii at intervals.

The sensor 150 is configured to detect the state of plasma. The sensor 150 is configured, for example, as the plasma probe. The sensor 150 is connected to the controller 200 via wiring (not shown). The controller 200 has a signal transmitter, and outputs a signal of a predetermined frequency generated by the signal transmitter to the sensor 150. The sensor 150 has an antenna part inside the processing container 101. A signal of a predetermined frequency that is input into the sensor 150 is transmitted from an antenna part to the plasma. The sensor 150 detects a current value of a signal reflected from a plasma side, as the plasma state, with respect to the signal transmitted to the plasma side. The sensor 150 outputs the detected current value to the controller 200. The controller 200 performs a frequency analysis on the input current value, and calculates an electron density, an ion density, and an electron temperature of the plasma. The controller 200 detects the electron density, the ion density, and the electron temperature of the plasma as the plasma state using each sensor 150. The sensor 150 may have any configuration as long as it can detect the plasma state.

The bottom wall portion 113 is provided with an opening, and an exhaust device 104 is installed via an exhaust pipe 116 connected to the opening. The exhaust device 104 is provided with a vacuum pump and a pressure control valve. The inside of the processing container 101 is evacuated via the exhaust pipe 116 by the vacuum pump of the exhaust device 104. A pressure in the processing container 101 is controlled by a pressure control valve of the exhaust device 104.

The mounting table 102 is formed in a disk shape. The mounting table 102 is formed of a dielectric material. For example, the mounting table 102 is formed of aluminum having an anodized surface, or a ceramic material, such as aluminum nitride (AlN). The substrate W is mounted on the upper surface of the mounting table 102. The mounting table 102 is supported by a base member 121 and a support member 120 formed of ceramics, such as cylindrical AlN, extending upward from the center of the bottom of the processing container 101. A guide ring 181 for guiding the substrate W is provided on the outer edge of the mounting table 102. Further, a lifting pin(s) (not shown) for lifting the substrate W is installed in the mounting table 102 to protrude from and be retracted into the upper surface of the mounting table 102.

Further, a resistance heating type heater 182 is embedded in the mounting table 102. The heater 182 is supplied with power from a heater power source 183 to heat the substrate W mounted on the mounting table 102. In addition, a thermocouple (not shown) is inserted into the mounting table 102, and the heating temperature of the substrate W may be controlled based on a signal from the thermocouple. An electrode 184 having the same size as the substrate W is embedded in the mounting table 102 above the heater 182. A DC power supply part 122 is electrically connected to the electrode 184. The DC power supply part 122 periodically applies a DC voltage to the electrode 184 in the mounting table 102. For example, the DC power supply part 122 includes a DC power supply and a pulse unit. The DC power supply part 122 turns on or off the DC voltage supplied from the DC power supply by the pulse unit to periodically apply the pulsed DC voltage to the electrode 184.

The gas supply mechanism 103 supplies various gases into the processing container 101. The gas supply mechanism 103 has gas introduction nozzles 123 and 124, gas supply pipes 125 and 126, and a gas supply part 127. The gas introduction nozzle 123 is fitted into an opening that is formed in the top wall portion 111 of the processing container 101. The gas introduction nozzle 124 is fitted into the opening formed in the sidewall portion 112 of the processing container 101. The gas supply part 127 is connected via the gas supply pipe 125 to each gas introduction nozzle 123. Further, the gas supply part 127 is connected via the gas supply pipe 126 to each gas introduction nozzle 124. The gas supply part 127 has a source of various gases. Further, the gas supply part 127 includes an opening and closing valve for starting and stopping the supply of various gases or a flow rate adjustment part for adjusting the flow rate of gas. The gas supply part 127 supplies various gases such as processing gas used for plasma processing.

The microwave introduction device 105 is installed above the processing container 101. The microwave introduction device 105 introduces electromagnetic waves (microwaves) into the processing container 101 to generate plasma.

The microwave introduction device 105 has a microwave output part 130 and an antenna unit 140. The microwave output part 130 generates microwaves, distributes the microwaves to a plurality of paths, and then outputs the microwaves. The antenna unit 140 introduces the microwaves, which are output from the microwave output part 130, into the processing container 101.

The microwave output part 130 has a microwave power source, a microwave oscillator, an amplifier, and a distributor. The microwave oscillator is a solid state, and oscillates microwaves (e.g., PLL oscillation) at 860 MHz, for example. The frequency of the microwaves is not limited to 860 MHz, and frequencies in the range of 700 MHz to 10 GHz, such as 2.45 GHz, 8.35 GHz, 5.8 GHz, or 1.98 GHz may be used. The amplifier amplifies the microwaves oscillated by the microwave oscillator. The distributor distributes the microwaves amplified by the amplifier into the plurality of paths. The distributor distributes the microwaves while matching impedance of an input side with impedance of an output side.

The antenna unit 140 has a plurality of antenna modules. In FIG. 1, three antenna modules of the antenna unit 140 are shown. Each antenna module has an amplification part 142 and a microwave radiation mechanism 143. The microwave output part 130 generates microwaves, distributes the microwaves, and outputs the microwaves to the respective antenna modules. The amplification part 142 of the antenna module mainly amplifies the distributed microwaves and outputs the microwaves to the microwave radiation mechanism 143. The microwave radiation mechanism 143 is installed in the top wall portion 111. The microwave radiation mechanism 143 radiates the microwaves output from the amplification part 142 into the processing container 101.

The amplification part 142 has a phase shifter, a variable gain amplifier, a main amplifier, and an isolator. The phase shifter changes the phase of microwaves. The variable gain amplifier adjusts the power level of the microwaves that are input into the main amplifier. The main amplifier is configured as a solid state amplifier. The isolator separates reflected microwaves that are reflected from the antenna part of the microwave radiation mechanism 143 to be described later and proceed to the main amplifier.

As shown in FIG. 1, the plurality of microwave radiation mechanism 143 is installed in the top wall portion 111. Further, the microwave radiation mechanism 143 has a tubular outer conductor, and an inner conductor installed in the outer conductor to be coaxial with the outer conductor. The microwave radiation mechanism 143 has a coaxial tube having a microwave transmission path between the outer conductor and the inner conductor, and an antenna part that radiates the microwaves into the processing container 101. A microwave transmitting plate 163 fitted into the top wall portion 111 is installed on the lower surface of the antenna part. The lower surface of the microwave transmitting plate 163 is exposed to the inner space of the processing container 101. The microwaves transmitted through the microwave transmitting plate 163 generate plasma in the space of the processing container 101.

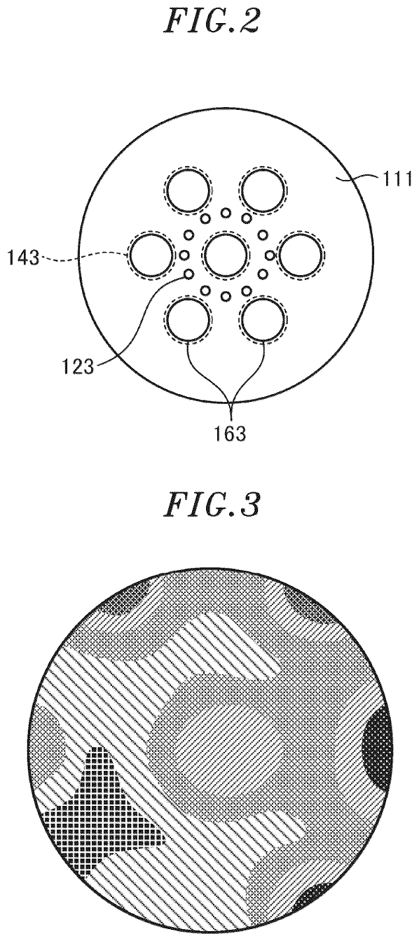

FIG. 2 is a diagram showing an example of the arrangement of the antenna module on the top wall portion 111 according to an embodiment. As shown in FIG. 2, seven microwave radiation mechanisms 143 of the antenna module are installed in the top wall portion 111. Six microwave radiation mechanisms 143 are arranged at the vertices of a regular hexagon, and one microwave radiation mechanism 143 is arranged at the center of the regular hexagon. Further, the microwave transmitting plates 163 are disposed on the top wall portion 111 to correspond to the seven microwave radiation mechanisms 143, respectively. These seven microwave transmitting plates 163 are arranged so that neighboring microwave transmitting plates 163 are equidistantly spaced. Also, the plurality of gas introduction nozzles 123 of the gas supply mechanism 103 are arranged to surround the central microwave transmitting plate 163. The number of antenna modules provided on the top wall portion 111 is not limited to seven. Although the sensor 150 is not illustrated in FIG. 2, a plurality of the sensors 150 are arranged in a region where the microwave transmitting plate 163 or the gas introduction nozzle 123 of the top wall portion 111 are not arranged. For instance, the sensors 150 are concentrically arranged at a plurality of radii from the center of the top wall portion 111.

The antenna unit 140 according to an embodiment controls the amplification part 142 of each antenna module to adjust the power of microwaves radiated from the microwave radiation mechanism 143 of each antenna module.

Further, as long as the power density of the microwaves may be appropriately controlled, a microwave plasma source having a single microwave introduction part with a size corresponding to that of the substrate W may be used.

The operation of the plasma processing apparatus 100 configured as described above is integrally by the controller 200. A user interface 210 and a storage part 220 are connected to the controller 200.

The user interface 210 includes an operation part, such as a keyboard, through which a process manager inputs a command to manage the plasma processing apparatus 100, or a display part, such as a display, which visualizes and displays the operation status of the plasma processing apparatus 100. The user interface 210 receives various operations. For instance, the user interface 210 receives a predetermined operation instructing the start of plasma processing.

The storage part 220 is a storage device that stores various pieces of data. For example, the storage part 220 is a storage device such as a hard disk, a Solid State Drive (SSD), or an optical disk. Further, the storage part 220 may be a semiconductor memory capable of rewriting data, such as a Random Access Memory (RAM), a flash memory, or a Non Volatile Static Random Access Memory (NVSRAM).

The storage part 220 stores an Operating System (OS) executed by the controller 200 or various recipes. For example, the storage part 220 stores various recipes including a recipe that executes the plasma processing. Further, the storage part 220 stores various pieces of data used in the recipe. Further, the program or data may be stored in a computer recording medium (e.g., hard disk, CD, flexible disk, semiconductor memory, etc.) that is readable by a computer. Alternatively, the program or data may be transmitted from another device, for example, via a dedicated line at any time and then be used online.

The controller 200 is a device that controls the plasma processing apparatus 100. The controller 200 has an electronic circuit such as a Central Processing Unit (CPU) or a Micro Processing Unit (MPU) or an integrated circuit such as an Application Specific Integrated Circuit (ASIC) or a Field Programmable Gate Array (FPGA). The controller 200 has an internal memory for storing a program defining various process sequences or control data, and executes various processes using them. The controller 200 functions as various processing parts by running various programs.

The controller 200 controls each part of the plasma processing apparatus 100. For example, the controller 200 controls each part of the plasma processing apparatus 100 to perform plasma processing according to the recipe of the recipe data stored in the storage part 220.

In the plasma processing apparatus 100, the substrate W is mounted on the mounting table 102. The plasma processing apparatus 100 performs plasma processing on the substrate W mounted on the mounting table 102. The plasma processing apparatus 100 generates plasma by the microwaves in the processing container 101. For example, the controller 200 controls the gas supply part 127 and the microwave introduction device 105, and introduces the microwaves from the microwave introduction device 105 into the processing container 101 to generate plasma while supplying the processing gas used for plasma processing from the gas supply part 127 into the processing container 101.

The plasma processing apparatus 100 periodically applies a DC voltage to the mounting table 102 in the processing container 101 where plasma is generated, and irradiates the substrate W with electrons in the plasma. For example, the controller 200 controls the DC power supply part 122, periodically applies the DC voltage from the DC power supply part 122 to the mounting table 102, and irradiates the substrate W with the electrons in the plasma.

During plasma processing, the plasma processing apparatus 100 detects the state of plasma by using the plurality of sensors 150, and estimates the state of the plasma in the processing container 101 based on the state of plasma obtained from the plurality of sensors 150. For example, the controller 200 uses the data obtained from the plurality of sensor 150 to obtain two-dimensional distribution representing the state of the plasma with respect to the installation positions of the plurality of sensors 150. Further, the controller 200 estimates the plasma state in the processing container 101 based on the two-dimensional distribution.

Here, the estimation of the plasma state will be described. FIG. 3 is a diagram showing an example of the two-dimensional distribution representing the plasma state according to an embodiment. FIG. 3 shows a two-dimensional plasma distribution at a specific height, for example, under the top wall portion 111 in the processing container 101 or above the substrate W. The processing container 101 defines a cylindrical space therein. For this reason, the two-dimensional plasma distribution at a specific height is shown as a circular two-dimensional distribution. As a characteristic quantity representing the characteristics of such a two-dimensional distribution, there are indicators such as an average value, a median value, a standard deviation, and non-uniformity (uniformity). The two-dimensional distribution is actually more complex, and is not fully characterized by indicators such as the average value, the median value, the standard deviation, and the non-uniformity.

On the other hand, a continuous function on a disk may be decomposed by an orthogonal function system. Examples of the orthogonal function system may include the Zernike polynomials and the Bessel function. A circular two-dimensional distribution may also be decomposed by the orthogonal function system.

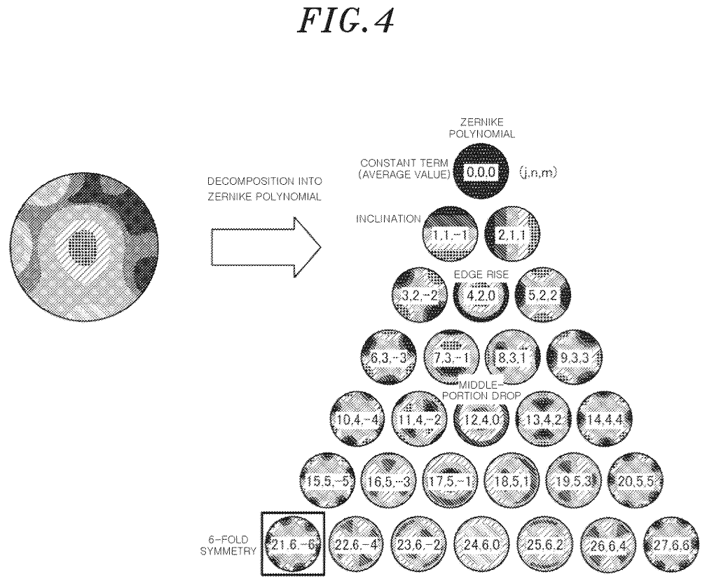

FIG. 4 is a diagram illustrating the decomposition of the two-dimensional distribution by the Zernike polynomials according to an embodiment. A circular two-dimensional distribution is shown on the left side of FIG. 4. The circular two-dimensional distribution is, for example, the two-dimensional plasma distribution at a specific height.

The circular two-dimensional distribution may be decomposed by the Zernike polynomials. The right side of FIG. 4 shows the distribution representing each term up to n=6 of the Zernike polynomials. The distribution representing each term of the Zernike polynomials is appended with (j, n, m).

Each term of the Zernike polynomials may be represented by the following Equations (1) and (2). n is a non-negative integer. m is an integer satisfying n≥|m|, and ρ is a radius vector (0≤ρ≤1). ϕ is a deflection angle. Since j is an index number that identifies each component of the Zernike polynomials, there are arbitrary methods of taking it, but it may be represented by, for example, Equation (3).

$${Z}_{n}^{m} ( ρ , ϕ ) = \{ \begin{matrix}{R}_{n}^{m} ( ρ ) cos ( m ϕ ) & m \geq 0 \\ {R}_{n}^{\vert m \vert} ( ρ ) sin ( \vert m \vert ϕ ) & m < 0\end{matrix} \qquad ( 1 )$$

$$\begin{matrix}n > \vert m \vert & 0 \leq ρ \leq 1 & 0 \leq ϕ \leq 2 π\end{matrix} \\ \begin{matrix}{R}_{n}^{m} ( ρ ) = {\sum }_{k = 0}^{\frac{n - m}{2}} \frac{{( - 1 )}^{k} ( n - k ) !}{k ! ( \frac{n + m}{2} - k ) ! ( \frac{n - m}{2} - k ) !} {ρ}^{n - 2 k} & ( n - m : even )\end{matrix} \qquad ( 2 )$$

$$j = \frac{n ( n + 2 ) + m}{2} \qquad ( 3 )$$

For example, (0, 0, 0) is a constant term corresponding to the average value of the circular two-dimensional distribution. (1, 1, −1) and (2, 1, 1) are terms representing an inclined distribution that continuously increases or decreases in either of a vertical direction or a horizontal direction. Further, (4, 2, 0) is a term representing an edge rise distribution in which a circular edge portion increases over the entire circumference. Furthermore, (12, 4, 0) is a term representing a middle-portion drop distribution in which an increase occurs as the circular edge portion and a central portion increase and a decrease occurs at a middle portion between the edge portion and the central portion. Further, (21, 6, −6) is a term representing a six-fold symmetric distribution in which increases and decreases alternately occur six times in a symmetrical arrangement at the circular edge portion.

The circular two-dimensional distribution may be decomposed into components of terms of the Zernike polynomials. By the decomposition, a component intensity indicating how much the circular two-dimensional distribution contains the component of each term of the Zernike polynomials is obtained for each term. The circular two-dimensional distribution may be reconstructed by adding all of the component intensity of each term obtained from the distribution of the terms of the Zernike polynomials.

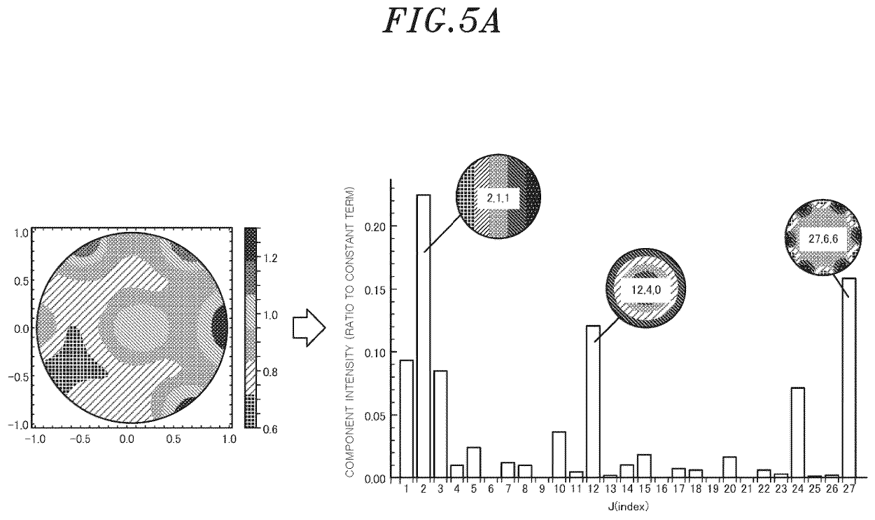

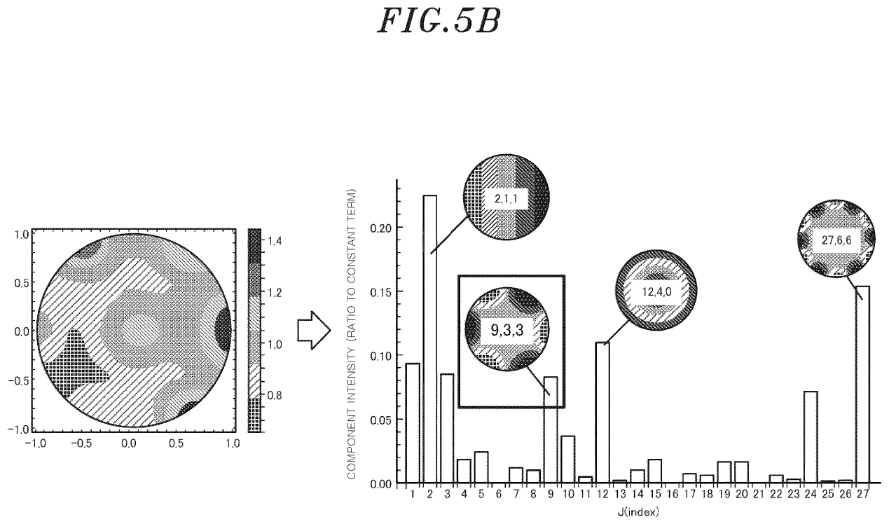

FIG. 5A is a diagram showing an example of the decomposition of the two-dimensional distribution according to an embodiment. A circular two-dimensional distribution is shown on the left side of FIG. 5A. A graph indicating component intensities of the terms obtained by decomposing the circular two-dimensional distribution on the left side into terms of the Zernike polynomials is shown on the right side of FIG. 5A. In the graph, the index number j representing each term of the Zernike polynomials is plotted on the horizontal axis, and the component intensity of each term is shown. The intensity used herein refers to the absolute value of a value decomposed by the Zernike polynomials. The component intensity is indicated as a ratio to a component intensity of the constant term. In FIG. 5A, the components intensities of terms such as (2, 1, 1), (12, 4, 0), and (27, 6, 6) are increased.

FIG. 5B is a diagram showing an example of the decomposition of the two-dimensional distribution according to an embodiment. A circular two-dimensional distribution is shown on the left side of FIG. 5B. A graph indicating component intensities obtained by decomposing the circular two-dimensional distribution on the left side into terms of the Zernike polynomials is shown on the right side of FIG. 5B. In the graph, the index number j representing each term of the Zernike polynomials is plotted on the horizontal axis, and the component intensity of each term is shown. The component intensity is indicated as a ratio to the constant term. The two-dimensional distribution in FIG. 5B is similar to the two-dimensional distribution in FIG. 5A, and it is difficult to visually distinguish between the two-dimensional distributions. However, in FIG. 5B, in addition to the terms (2, 1, 1), (12, 4, 0), and (27, 6, 6), the component intensity of the term (9, 3, 3) is increased.

By decomposing the Zernike polynomials into the components of terms in this way, it becomes easy to distinguish a difference in the two-dimensional distribution from the component intensity of each term.

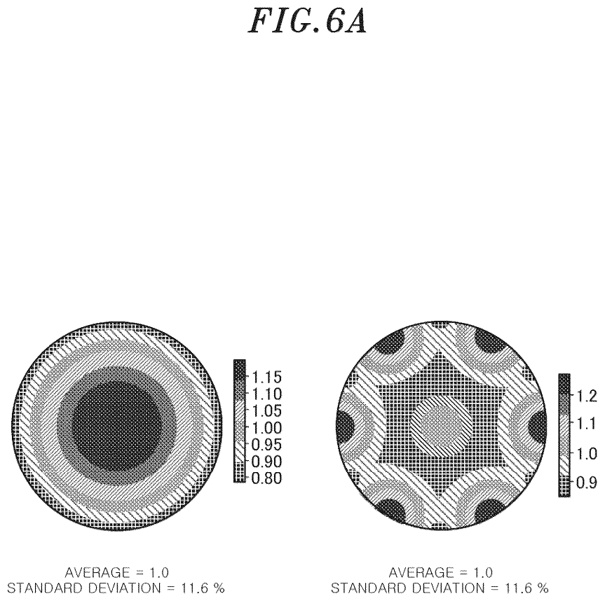

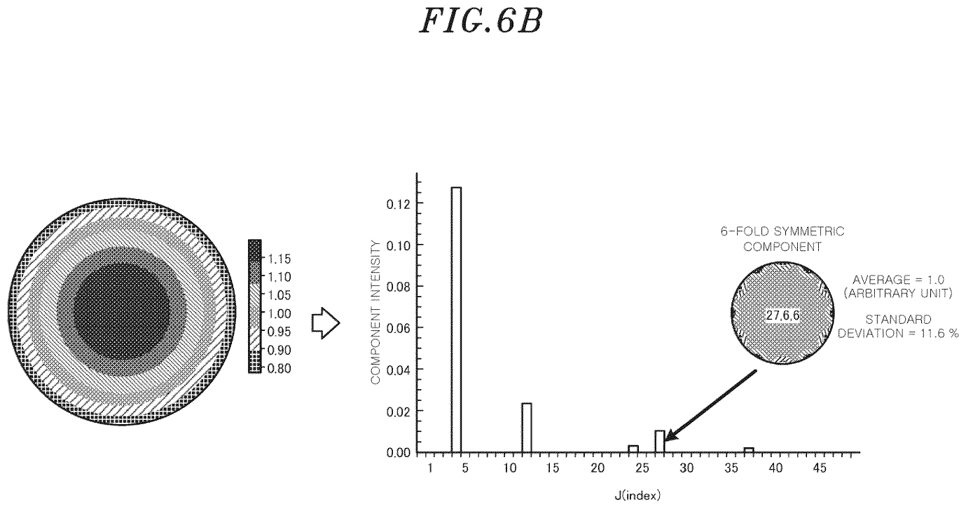

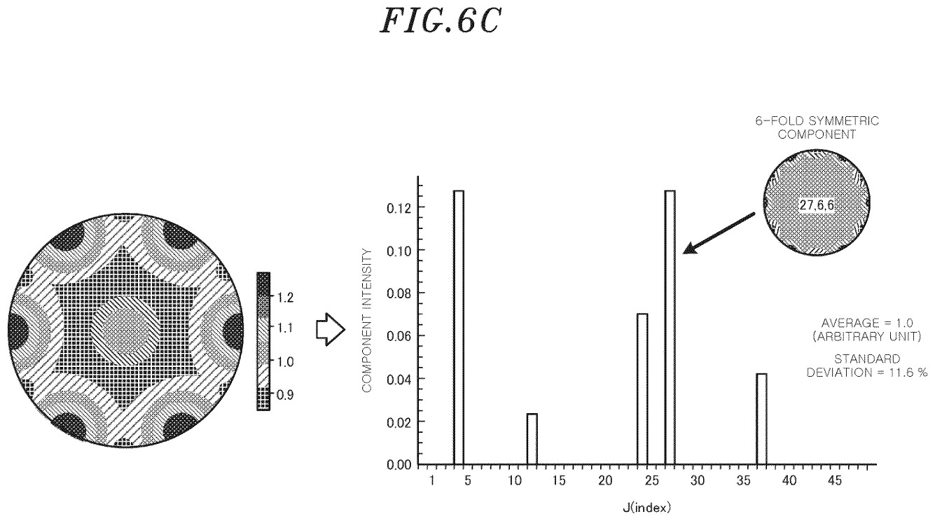

FIG. 6A is a diagram showing an example of two-dimensional distribution according to an embodiment. Two different circular two-dimensional distributions are shown on the left and right sides of FIG. 6A. Both of the two circular two-dimensional distributions on the left and right sides have the average of 1.0 and the standard deviation of 11.6%. FIGS. 6B and 6C are diagrams showing the component intensity of each term of the Zernike polynomials according to an embodiment. FIG. 6B is a graph showing the component intensities obtained by decomposing the circular two-dimensional distribution shown on the left side of FIG. 6A into each term of the Zernike polynomials. FIG. 6C is a graph showing the component intensities obtained by decomposing the circular two-dimensional distribution shown on the right side of FIG. 6A into each term of the Zernike polynomials. The two circular two-dimensional distributions have a clear difference in the component intensity of each term of the Zernike polynomials. For example, a large difference occurs in the component intensity of the term (27, 6, 6). By decomposing the Zernike polynomials into the components of terms in this way, it is possible to clearly distinguish differences that do not appear in the average and standard deviation.

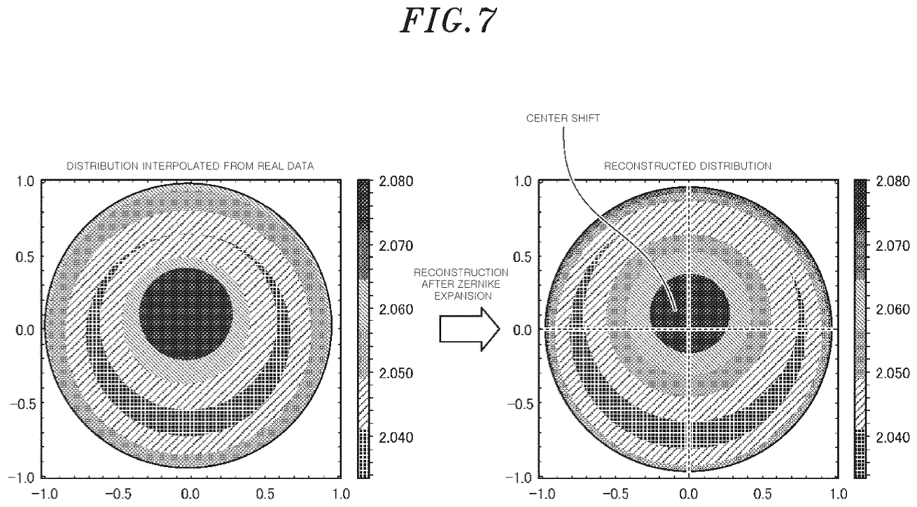

FIG. 7 is a diagram showing an example of two-dimensional distribution according to an embodiment. Two circular two-dimensional distributions are shown on the left and right sides of FIG. 7. The circular two-dimensional distribution on the left is the result of measuring at 49 points in the circle and interpolating the measured data of the 49 points to obtain the circular two-dimensional distribution. The circular two-dimensional distribution on the right is the distribution reconstructed by decomposing the circular two-dimensional distribution on the left into the components of terms of the Zernike polynomials to obtain the component intensity of each term, and then adding each term of the Zernike polynomials to the obtained component intensity of each term. The reconstruction may be performed by decomposing the Zernike polynomials into components of terms and adding each term of the Zernike polynomials with the component intensity of each term. Thus, by decomposing the Zernike polynomials into components of terms and adding each term of the Zernike polynomials with the component intensity of each term, it is possible to interpolate a small number of data points with a continuous function, and to easily determine the situation of the two-dimensional distribution. For example, as for the circular two-dimensional distribution on the right, it may be determined that the center of the two-dimensional distribution is shifted from the center of the circle.

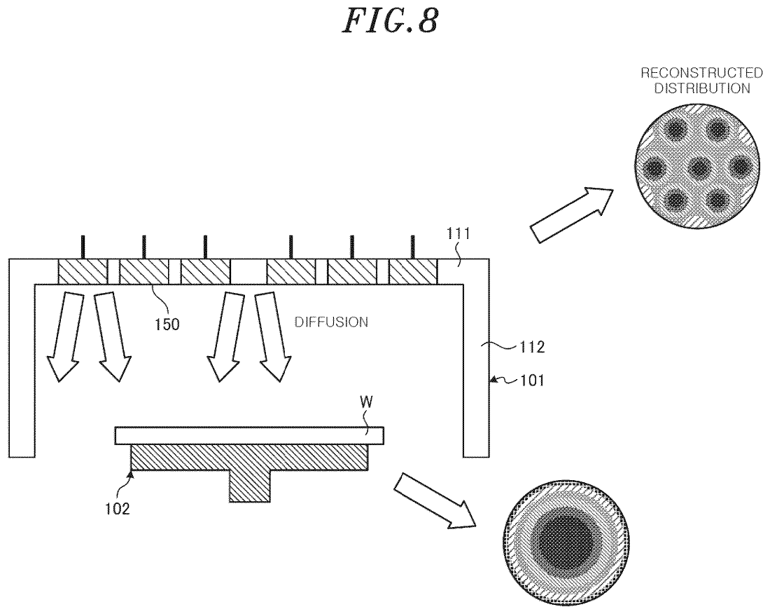

FIG. 8 is a diagram illustrating the flow of estimating a plasma state according to an embodiment. The plasma processing apparatus 100 detects the plasma state by the plurality of sensors 150 during plasma processing. Further, the plasma processing apparatus 100 estimates the state of plasma in the processing container 101 based on the plasma state obtained from the plurality of sensors 150. For example, the controller 200 detects, by the plurality of sensors 150, the electron density of the plasma as the plasma state. Further, the ion density or electron temperature of the plasma may be detected as the plasma state. The controller 200 obtains the two-dimensional distribution of the electron density of the plasma from the electron density of the plasma detected by the plurality of sensors 150. For example, the controller 200 decomposes the electron density of the plasma detected by each sensor 150 into the component of each term of the Zernike polynomials with respect to the installation positions of the plurality of sensors 150, and then obtains the component intensity of each term of the Zernike polynomials. Further, as illustrated in FIG. 7, the controller 200 may obtain the two-dimensional distribution of the electron density of the plasma by performing interpolation from the electron density of the plasma detected by each sensor 150. Moreover, the controller 200 may decompose the obtained two-dimensional distribution of the electron density of the plasma into the component of each term of the Zernike polynomials, and then obtain the component intensity of each term of the Zernike polynomials.

The controller 200 reconstructs the two-dimensional distribution of the electron density of the plasma by adding each term of the Zernike polynomials with the obtained component intensity of each term. An example of the reconstructed two-dimensional distribution of the electron density of the plasma is shown on the upper portion of the right of FIG. 8. The reconstructed two-dimensional distribution is the two-dimensional distribution on the plane at the height of the installation position of the sensor 150.

The electron density distribution of the plasma at any position in the processing container 101 may be calculated by solving a diffusion equation. The controller 200 estimates the distribution of the electron density of the plasma at any position (e.g., right above the substrate W) in the processing container 101, by solving the diffusion equation from the reconstructed two-dimensional distribution.

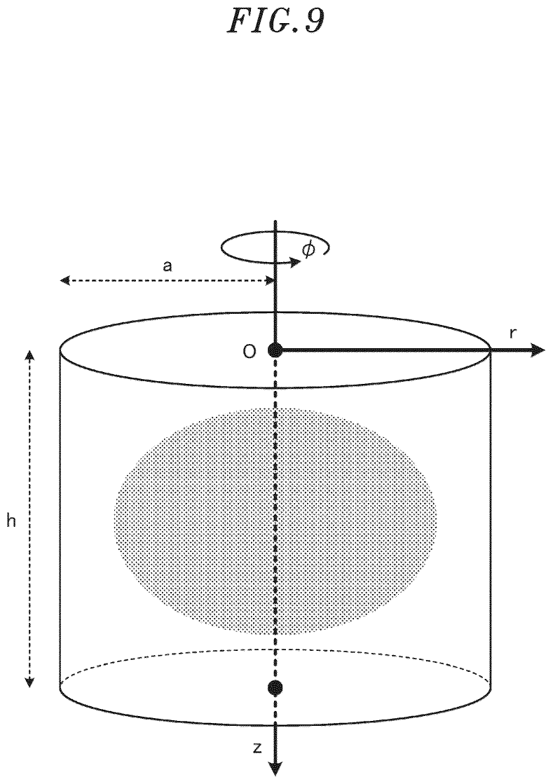

As shown in FIG. 9, the internal space of the processing container 101 is a cylindrical space. FIG. 9 is a diagram showing the cylindrical space in the processing container 101 according to an embodiment. r is a parameter indicating a radial position from the central axis of the cylinder. 0 is a parameter indicating a rotation angle around the central axis. z is a parameter indicating a position in a height direction along the central axis of the cylinder. A radius from the central axis of the cylinder is denoted by a. A height along the central axis of the cylinder is denoted by h. Boundary conditions are defined in the cylindrical space to correspond to the processing container 101.

Assuming that the electron density distribution at (r, ϕ, z) of the cylindrical space in the processing container 101 is n(r, ϕ, z), the diffusion equation will be expressed as the following Equation (4).

∇²n=0 (4)

The controller 200 estimates the state of the plasma in the processing container 101, by solving the diffusion equation from the reconstructed two-dimensional distribution. For example, the controller 200 estimates the distribution of the electron density of the plasma in the processing container 101, by solving the diffusion equation from the reconstructed two-dimensional distribution. Thereby, the plasma processing apparatus 100 may estimate the state of the plasma in the processing container 101. For example, the controller 200 estimates the distribution of the electron density of the plasma on the upper surface of the mounting table 102 (i.e., right above the substrate W). An example of the estimated two-dimensional distribution of the electron density of the plasma on the upper surface of the mounting table 102 is shown on the lower portion of the right of FIG. 8. Thereby, the state of the plasma on the upper surface of the mounting table 102 may be estimated. Further, the controller 200 may estimate the electron density of the plasma at any position in the processing container 101, by solving the diffusion equation from the reconstructed two-dimensional distribution. Further, the controller 200 may estimate the electron density of the plasma at any position in the processing container 101, by solving the diffusion equation from un-reconstructed two-dimensional distribution. For example, the controller 200 may estimate the two-dimensional distribution of the electron density of the plasma at any height in the processing container 101.

The controller 200 performs the above-described processing by appropriately detecting the plasma state using the plurality of sensors 150 during plasma processing, thereby estimating the state of the plasma in the processing container 101. For example, the controller 200 estimates the two-dimensional distribution of the electron density of the plasma in the processing container 101. Thereby, the controller 200 may estimate the two-dimensional distribution of the electron density of the plasma in the processing container 101 in real time during plasma processing.

The controller 200 outputs the estimated plasma state. For example, the controller 200 outputs the estimated plasma state to the user interface 210. For example, the controller 200 outputs the estimated two-dimensional distribution of the electron density of the plasma in the processing container 101 to the user interface 210. This allows a process manager to check the two-dimensional distribution of the electron density during plasma processing in real time. Further, the controller 200 may output the data of the estimated plasma state to another device. Further, the controller 200 may output and store the data of the estimated plasma state in the storage part 220 or an external storage device. Therefore, it is possible to check the plasma state after the plasma processing is performed.

The component intensity of each term of the Zernike polynomials is susceptible to a change in two-dimensional distribution.

Therefore, the controller 200 detects an abnormality from the component intensity of each term of the Zernike polynomials obtained by decomposing the electron density of the plasma detected by each sensor 150. For example, the normal range of the component intensity of each term of the Zernike polynomials is previously determined through an experiment or a simulation. The controller 200 determines whether the component intensity of each term of the Zernike polynomials obtained by decomposing the electron density of the plasma detected by each sensor 150 is within the normal range. The controller 200 determines a state as a normal state when all the component intensities of each term of the Zernike polynomials are within the normal range, and determines the state as an abnormal state when any term is outside the normal range.

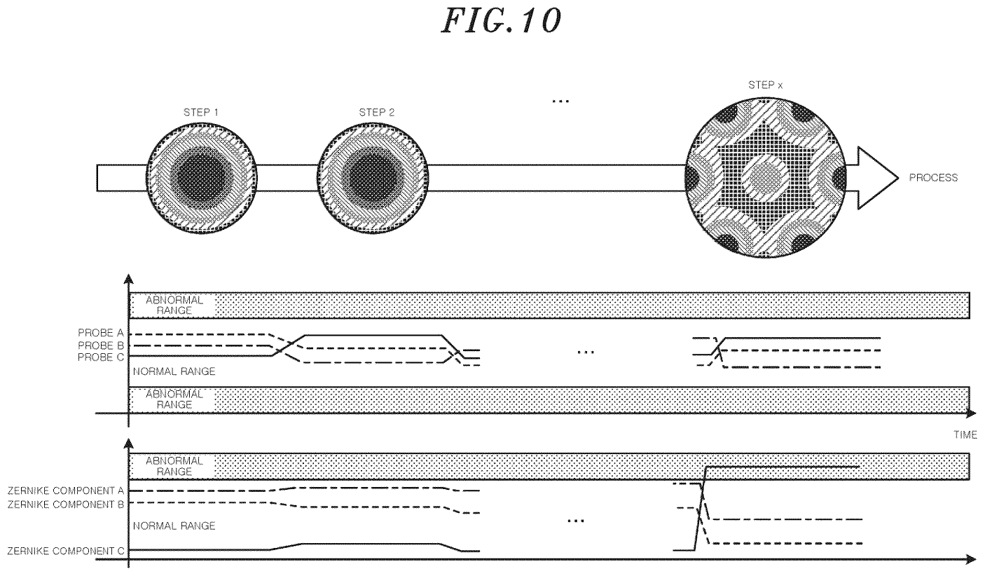

FIG. 10 is a diagram illustrating an example of abnormality detection according to an embodiment. The upper portion of FIG. 10 shows the two-dimensional distribution of the plasma as step 1, step 2, . . . step x. Step 1, step 2, . . . step x may be the two-dimensional distribution of plasma for each substrate W when a plurality of substrates W are subjected to plasma processing. Further, step 1, step 2, . . . step x may be the two-dimensional distribution of plasma at a predetermined timing, such as every predetermined period, when one substrate W is subjected to plasma processing.

The lower portion of FIG. 10 shows an example of changes in the values detected by the sensors 150 at step 1, step 2, . . . step x, and the value of the component intensity of each item of the Zernike polynomials. Probes A to C show changes in values detected by the plurality of sensors 150 (three sensors in this case). Zernike components A to C show changes in the values of the component intensities of the terms of the Zernike polynomials.

The value detected by the sensor 150 is a value corresponding to the plasma state at a position where the sensor 150 is installed. For this reason, there is a possibility that the abnormality in the distribution may not be noticed with the value detected by the sensor 150. For example, even if the two-dimensional distribution becomes the same as step x, there is a possibility that the abnormality in the distribution may not be noticed.

Meanwhile, the component intensity of each term of the Zernike polynomials is susceptible to a change in two-dimensional distribution. For instance, when the two-dimensional distribution becomes the same as step x, the Zernike component C deviates from the normal range and becomes within an abnormal range. Therefore, the controller 200 may detect the abnormality in the two-dimensional distribution by determining whether the component intensity of each term of the Zernike polynomials, which is obtained by decomposing the plasma electron density detected by each sensor 150, is within the normal range.

When detecting the abnormality, the controller 200 outputs that the abnormality has occurred. For example, the controller 200 outputs to the user interface 210 that the abnormality has occurred. This allows a process manager to grasp the occurrence of the abnormality in real time. Further, the controller 200 may output data indicating that the abnormality has occurred to another device. Furthermore, the controller 200 may output and store the data indicating that the abnormality has occurred in the storage part 220 or the external storage device. Therefore, it is possible to later check whether there is the abnormality in the plasma processing that has been performed.

Further, the controller 200 periodically detects the electron density of the plasma by the plurality of sensors 150 during the plasma processing process, thereby obtaining the component intensity of each term of the Zernike polynomials, and monitoring a change in the component intensity of each term. This allows the controller 200 to detect a temporary or short-term change in plasma during the process.

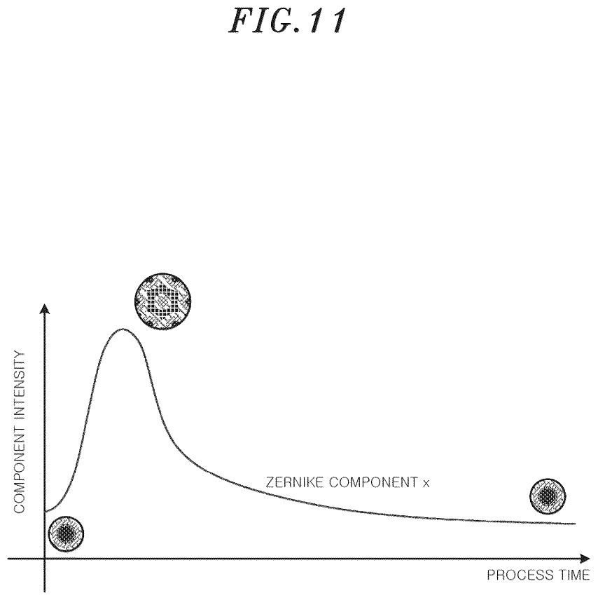

FIG. 11 is a diagram illustrating an example of abnormality detection according to an embodiment. In FIG. 11, a change in the Zernike component x during the plasma processing process is shown. The Zernike component x indicates a change in the value of the component intensity of any one term of the Zernike polynomials. The component intensity of each term of the Zernike polynomials is susceptible to the temporary or short-term change of the plasma. For example, the Zernike component x is greatly changed due to the temporary or short-term change of the plasma. Therefore, the controller 200 may monitor the change in the component intensity of each term of the Zernike polynomials during the process, so that it is possible to detect the temporary or short-term change of the plasma during the process. For example, the controller 200 may monitor the change in the component intensity of each term of the Zernike polynomials during the process, and may detect whether the component intensity of any term has changed beyond an allowable value, so that it is possible to detect that the temporary or short-term change in the plasma has occurred.

When the component intensity of any term has changed beyond the allowable value, the controller 200 outputs that the plasma has changed temporarily or in a short time. For example, the controller 200 outputs the temporary or short-term change in the plasma to the user interface 210. Thus, the process manager can grasp the temporary or short-term change in the plasma in real time. Further, the controller 200 may output data indicating the plasma has changed temporarily or in a short time to another device, or may output and store the data in the storage part 220 or the external storage device.

Further, the component intensity of each term of the Zernike polynomials may be used as follows.

The substrate W is changed, and then the substrate W is subjected to the plasma processing under various conditions by the plasma processing apparatus 100. The controller 200 detects the electron density of the plasma by the plurality of sensors 150 during the plasma processing, and obtains the component intensity of each term of the Zernike polynomials. The result of the plasma processing is measured from the substrate W that is subjected to the plasma processing. For example, when the plasma processing is film formation processing, the film formation distribution on the substrate W is measured. Whenever the plasma processing is performed, a data set in which the processing result is associated with the component intensity of each term of the Zernike polynomials is generated, machine learning is performed, and a first predictive model is generated. The machine learning may be performed by the controller 200 or another device. The storage part 220 stores the data of the generated first predictive model. The first predictive model learns a relationship between the processing result of the plasma processing and the component intensity of each term of the Zernike polynomials. Therefore, the first predictive model may predict the processing result from the component intensity of each term of the Zernike polynomials obtained from the detection result of the plurality of sensors 150 when the substrate W is subjected to plasma processing. For example, the first predictive model may predict the film formation distribution on the substrate W.

The first predictive model may predict how the processing result changes, when the component intensity of each term of the Zernike polynomials changes. Further, the first predictive model may predict how the component intensity of each term of the Zernike polynomials will change so as to change the processing result to a desired state. For example, the first predictive model may predict what the component intensity of each term of the Zernike polynomials should be so as to obtain a desired state of film formation distribution on the substrate W when film formation is performed on the substrate W by plasma processing.

Whenever the plasma processing is performed, a data set in which the processing condition of the plasma processing is associated with the component intensity of each term of the Zernike polynomials is generated, machine learning is performed, and a second predictive model is generated. The machine learning may be performed by the controller 200 or another device. The storage part 220 stores the data of the generated second predictive model. The second predictive model learns a relationship between the processing condition of the plasma processing and the component intensity of each term of the Zernike polynomials. Therefore, the second predictive model may predict how the component intensity of each term of the Zernike polynomials will change when the processing condition of the plasma processing is changed. Further, the second predictive model may predict the processing condition of the plasma processing to make the component intensity of each term of the Zernike polynomials into a desired component intensity.

The controller 200 predicts the component intensity of each term of the Zernike polynomials, which gives a predetermined processing result on the substrate W, by the first predictive model. For example, when film formation is performed on the substrate W by the plasma processing, the controller 200 predicts the component intensity of each term of the Zernike polynomials, which results in a predetermined film formation distribution on the substrate W, using the first predictive model. The controller 200 predicts the processing condition of the plasma processing in which the component intensity of each term of the Zernike polynomials becomes the predicted component intensity, using the second predictive model. Thereby, the controller 200 may obtain the processing condition of the plasma processing for obtaining a predetermined processing result on the substrate W. For example, the controller 200 may obtain the processing condition of the plasma processing for obtaining the predetermined film formation distribution on the substrate W.

Further, the substrate W is changed, and then the substrate W is subjected to the plasma processing under various conditions by the plasma processing apparatus 100. The controller 200 detects the electron density of the plasma by the plurality of sensors 150 during the plasma processing, and obtains the component intensity of each term of the Zernike polynomials. In addition, abnormality occurring in the plasma processing is measured. For example, a reflected-wave intensity and particle generation in plasma processing are measured. Whenever the plasma processing is performed, a data set in which the measurement result of the abnormality is associated with the component intensity of each term of the Zernike polynomials is generated, and machine learning is performed. The machine learning may be performed by the controller 200 or another device. The machine learning determines how the component intensity of each term of the Zernike polynomials contributes to the abnormality. This makes it possible to specify which term component intensity of the Zernike polynomials has an effect on the abnormality, and to specify the potential cause of the abnormality.

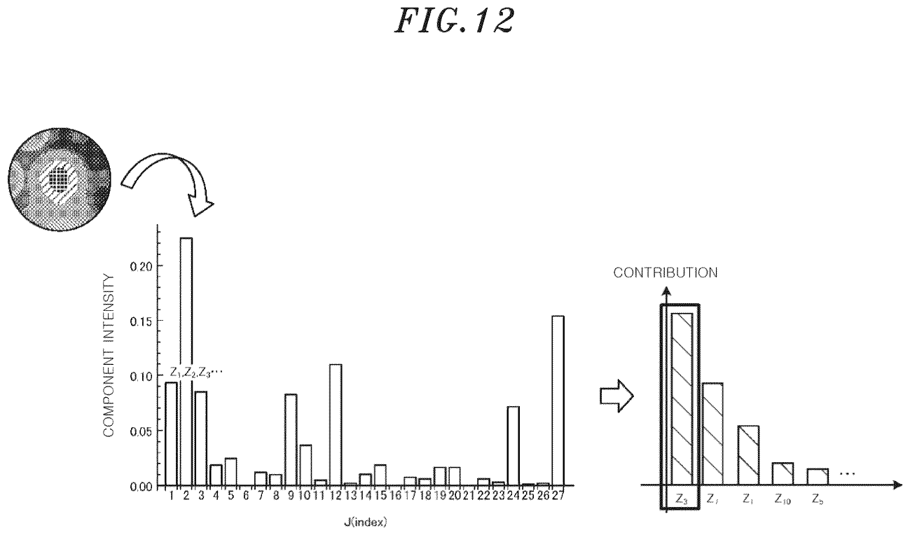

FIG. 12 is a diagram illustrating an example of illustrating the influence of the component intensity of each term of the Zernike polynomials on abnormality according to an embodiment. The left side of FIG. 12 shows the two-dimensional distribution of the plasma in plasma processing and the component intensity of each term of the Zernike polynomials obtained by detecting the electron density of the plasma with the plurality of sensors 150 during plasma processing. For example, the number of particles adhering to the substrate W is counted as the abnormality occurring in the plasma processing. Further, a data set in which the number of particles is associated with the component intensity of each term of the Zernike polynomials is generated, and machine learning is performed. On the right side of FIG. 12, the terms of the Zernike polynomials are shown in the descending order of contribution to the number of particles obtained by the machine learning. Z₃, Z₇, Z₁, Z₁₀, Z₅ . . . represent terms of the Zernike polynomials. For example, when the term of Z₃ is high, it may be specified that the number of particles is high.

The controller 200 outputs a specific result. For example, the controller 200 outputs the contribution and the term of the Zernike polynomials to the user interface 210 in the descending order of contribution. This allows the process manager to grasp which term of the Zernike polynomials influences the abnormality. Further, the controller 200 may output data indicating a specific result to another device, and may output and store the data in the storage part 220 or the external storage device.

[Plasma State Estimation Method]

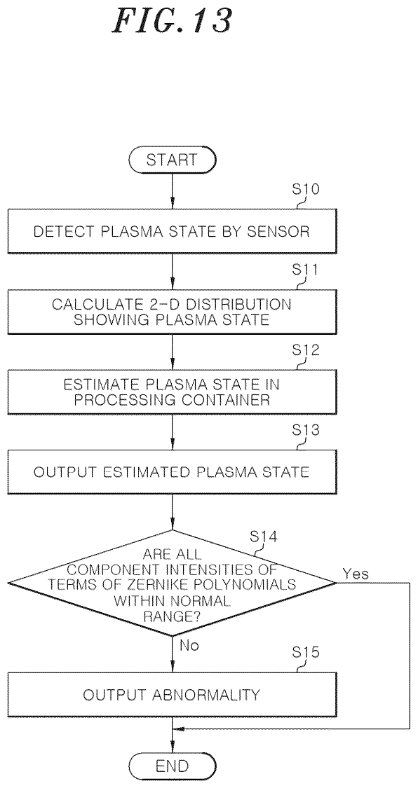

Next, the flow of plasma state estimation processing by a plasma state estimation method according to an embodiment will be described. FIG. 13 is a flowchart showing an example of the flow of plasma state estimation processing according to an embodiment. The plasma state estimation processing is performed at a predetermined timing during plasma processing.

The controller 200 detects the state of plasma using each of the plurality of sensors 150 (step S10). For example, the controller 200 detects the electron density of the plasma, as the plasma state, using each of the plurality of sensors 150.

The controller 200 obtains the two-dimensional distribution showing the plasma state on the basis of the installation positions of the plurality of sensors 150, by using the data obtained from the plurality of sensors 150 (step S11). For example, the controller 200 decomposes the electron density of the plasma detected by each sensor 150 into the components of each term of the Zernike polynomials, on the basis of the installation positions of the plurality of sensors 150, and obtains the component intensity of each term of the Zernike polynomials. Further, the controller 200 adds each term of the Zernike polynomials with the obtained component intensity of each term to reconstruct the two-dimensional distribution of the electron density of the plasma.

The controller 200 estimates the plasma state in the processing container 101 based on the obtained two-dimensional distribution showing the plasma state (step S12). For example, the controller 200 estimates the two-dimensional distribution of the electron density of the plasma at a specific height in the processing chamber 101, by solving the diffusion equation from the reconstructed two-dimensional distribution.

The controller 200 outputs the estimated plasma state (step S13). For instance, the controller 200 outputs the estimated two-dimensional distribution of the electron density of the plasma in the processing chamber 101 to the user interface 210.

The controller 200 determines whether the component intensity of each term of the Zernike polynomials obtained by decomposing the plasma electron density detected by each sensor 150 is within a predetermined normal range (step S14).

When all the component intensities of each term of the Zernike polynomials are within the normal range (step S14:Yes), the controller 200 determines that it is normal, and terminates the process.

On the other hand, when any term is out of the normal range (step S14:No), the controller 200 determines that it is abnormal, outputs that the abnormality has occurred (step S15), and terminates the process.

Through the plasma state estimation method according to an embodiment, the state of the plasma in the processing container 101 may be estimated.

In the above-described embodiment, since the microwave radiation mechanism 143 is arranged at the central position of the top wall portion 111, a case where the sensor 150 is provided at a position different from the central position of the top wall portion 111 has been described as an example. However, when the microwave radiation mechanism 143 is installed at a position different from the central position of the top wall portion 111, it is preferable that the sensor 150 is arranged at the central position of the top wall portion 111.

In the above-described embodiment, a case where the sensor 150 is disposed on the top wall portion 111 has been described as an example. However, the present disclosure is not limited thereto. The sensor 150 may be placed anywhere as long as it may detect the state of the plasma in the processing container 101.

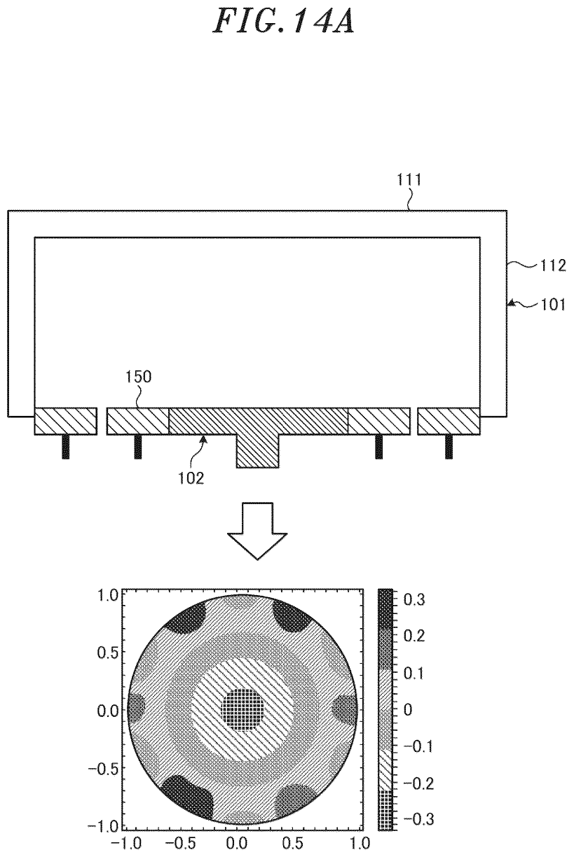

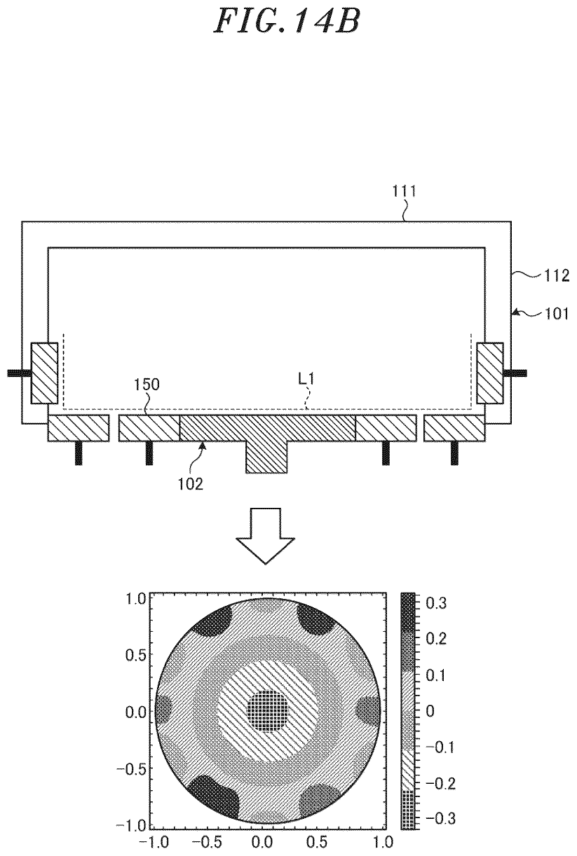

FIG. 14A is a diagram showing an example of the arrangement of the sensors 150 according to an embodiment. In FIG. 14A, the sensors 150 are arranged on the periphery of the mounting table 102 or around the mounting table 102. The controller 200 obtains the two-dimensional distribution showing the state of the plasma on the upper surface of the mounting table 102, through the data obtained from the plurality of sensors 150. The lower portion of FIG. 14A shows the two-dimensional distribution on the upper surface of the mounting table 102. The controller 200 may estimate the state of the plasma in the processing container 101 by solving the diffusion equation based on the obtained two-dimensional distribution on the upper surface of the mounting table 102.

FIG. 14B is a diagram showing an example of the arrangement of the sensors 150 according to an embodiment. In FIG. 14B, the sensors 150 are arranged on the sidewall portion 112 around the mounting table 12, in addition to the periphery of the mounting table 102 or around the mounting table 102. Based on the data obtained from the plurality of sensors 150, the controller 200 obtains the two-dimensional distribution showing the state of plasma on the upper surface of the mounting table 102 and the surface along the sidewall portion 112 around the mounting table 102, as shown by the line L1. The lower portion of FIG. 14B shows the two-dimensional distribution on the surface along the line L1. The controller 200 may estimate the state of the plasma in the processing container 101 by solving the diffusion equation based on the two-dimensional distribution on the surface along the line L1.

In the above-described embodiment, a case where the plasma processing apparatus of the present disclosure is the plasma processing apparatus 100 generating plasma by the microwaves has been described as an example. However, the present disclosure is not limited thereto. The plasma processing apparatus of the present disclosure may be of any type. For example, the plasma processing apparatus of the present disclosure may be a Capacitively Coupled Plasma (CCP) type, an Inductively-coupled plasma (ICP) type, or a plasma processing apparatus that excites gas by surface waves. The Capacitively Coupled Plasma type plasma processing apparatus provides electrodes on the top wall portion 111 and the mounting table 102, for example, thus generating plasma between the top wall portion 111 and the mounting table 102. Since the microwave radiation mechanism 143 is not arranged on the top wall portion 111, the sensor 150 may be arranged at a high degree of freedom, and the sensor 150 may also be arranged at the central position of the top wall portion 111.

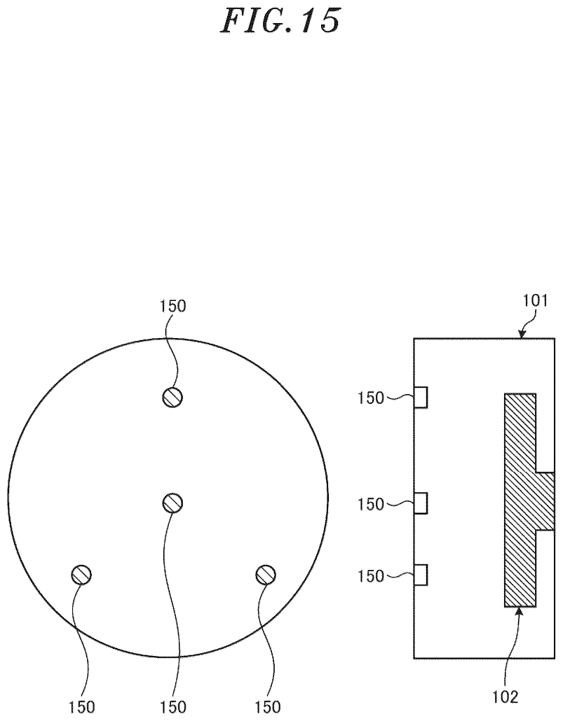

The sensors 150 may be arranged to at least obtain the two-dimensional distribution representing the plasma state. FIG. 15 is a diagram showing an example of the arrangement of the sensors 150 according to an embodiment. A plan view of the top wall portion 111 of the processing container 101 is shown on the left side of FIG. 15. A right side view of the processing container 101 is shown on the right side of FIG. 15. In FIG. 15, three sensors 150 are arranged in three directions from the center of the top wall portion 111. It is preferable that the three directions form the angle of about 120° with each other. The two-dimensional distribution is obtained by arranging the sensors 150 in three directions. The sensor 150 may be preferably arranged at the central position of the top wall portion 111. In FIG. 15, the sensor 150 is also arranged at the central position of the top wall portion 111. In this way, the sensor 150 is also arranged at the central position of the top wall portion 111, and the two-dimensional distribution representing the plasma state is obtained from the data obtained from the four sensors 150, thereby enhancing the accuracy of the two-dimensional distribution.

Further, in the above-described embodiment, a case where the Zernike polynomials is used as the orthogonal function system has been described as an example. However, the present disclosure is not limited thereto. Any orthogonal function system may be used as long as it may decompose the circular two-dimensional distribution. For example, the Bessel function may be used.

In the above-described embodiment, a case where film is formed by plasma processing has been described as an example. However, the present disclosure is not limited thereto. Any plasma processing such as etching or ashing is possible.

As described above, the plasma processing apparatus 100 according to an embodiment has the processing container 101, the plurality of sensors 150, and the controller 200. The mounting table 102 on which the substrate W is mounted is disposed in the processing container 101 in which plasma processing is performed. The plurality of sensors 150 detect the state of plasma generated in the processing container 101. The controller 200 estimates the state of the plasma in the processing container 101 based on the plasma state obtained from the plurality of sensors 150. The controller 200 obtains the two-dimensional distribution showing the plasma state with respect to the installation positions of the plurality of sensors 150 by the data obtained from the plurality of sensors 150, and estimates the state of the plasma in the processing container 101 based on the obtained two-dimensional distribution. Thereby, the plasma processing apparatus 100 may estimate the state of the plasma in the processing container 101.

Further, the controller 200 obtains the two-dimensional distribution by interpolating a state between the installation positions of the plurality of sensors 150 using the orthogonal function system, from data obtained from the plurality of sensors 150. The orthogonal function system uses the Zernike polynomials. Thereby, the plasma processing apparatus 100 may obtain the two-dimensional distribution even with a small number of data points.

The controller 200 decomposes the data obtained from the plurality of sensors 150 into the components of each term of the Zernike polynomials, and reconstructs each term of the Zernike polynomials with the component intensity of each decomposed term, thus obtaining the two-dimensional distribution. Thereby, the plasma processing apparatus 100 may reconstruct the two-dimensional distribution from the data obtained from the plurality of sensors 150 to easily determine the distribution state.

In addition, the controller 200 detects the abnormality depending on whether the component intensity of each decomposed term of the Zernike polynomials is within a predetermined normal range. Thereby, the plasma processing apparatus 100 may detect the abnormality of the two-dimensional distribution.

The controller 200 monitors the component intensity of each term of the Zernike polynomials obtained by decomposing the data obtained from the plurality of sensors 150 during plasma processing, and detects whether the component intensity of any term has changed beyond the allowable value. Thereby, the plasma processing apparatus 100 may detect the temporary or short-term change in the plasma during the plasma processing process.

Further, the controller 200 performs the machine learning on a data set in which the measurement result of the abnormality occurring during the plasma processing is associated with the component intensity of each decomposed term of the Zernike polynomials, and specifies the component intensity of the term of the Zernike polynomials that contributes highly to the abnormality. Thereby, the plasma processing apparatus 100 may specify which term component intensity of the Zernike polynomials has an effect on the abnormality, and to specify the potential cause of the abnormality.

The plasma processing apparatus 100 according to an embodiment further has the storage part 220. The storage part 220 stores the first predictive model that learns the relationship between the result of the plasma processing and the component intensity of each term of the Zernike polynomials, and the second predictive model that learns a relationship between the processing condition of the plasma processing and the component intensity of each term of the Zernike polynomials. The controller 200 predicts the component intensity of each term of the Zernike polynomials which gives a predetermined processing result on the substrate W, by the first predictive model, and predicts the processing condition of the plasma processing in which the component intensity of each term of the Zernike polynomials becomes the predicted component intensity, by the second predictive model. Thereby, the plasma processing apparatus 100 may obtain the processing condition of the plasma processing for obtaining a predetermined processing result.

The controller 200 estimates the state of the plasma in the processing container 101, by solving the diffusion equation based on the obtained two-dimensional distribution. Thereby, the plasma processing apparatus 100 may obtain the state of the plasma at any position (e.g., position right above the substrate W) in the processing container 101.

Although an embodiment has been described, it is to be understood that the embodiment is merely illustrative but is not restrictive. Various changes may be made on the above-described embodiment. In addition, the above-mentioned embodiment may be omitted, substituted, or changed in various forms without departing from the scope of the claims.

In the above embodiment, the case where the substrate W is a semiconductor wafer has been described as an example, but the present disclosure is not limited thereto. Any substrate W may be used.

Further, it should be contemplated that the foregoing embodiment is merely illustrative but is not restrictive. In practice, the above embodiment may be implemented in various forms. The above embodiment may be omitted, substituted, or changed in various forms without departing from the scope of the appended claims.

Regarding the above embodiment, the following appendices are disclosed.

(Appendix 1)

A plasma processing apparatus comprising:
a processing container in which a mounting table on which a substrate is mounted is arranged and plasma processing is performed;
a plurality of sensors for detecting a state of plasma generated in the processing container; and
a controller for estimating a state of plasma in the processing container based on the state of plasma obtained from the plurality of sensors,
wherein the controller obtains a two-dimensional distribution representing the state of plasma with respect to installation positions of the plurality of sensors, from data obtained from the plurality of sensors, and estimates the state of plasma in the processing container based on the obtained two-dimensional distribution.

(Appendix 2)

The plasma processing apparatus of appendix 1, wherein the controller obtains the two-dimensional distribution by interpolating a state between the installation positions of the plurality of sensors using an orthogonal function system, from the data obtained from the plurality of sensors.

(Appendix 3)

The plasma processing apparatus of appendix 2, wherein the orthogonal function system is Zernike polynomials.

(Appendix 4)

The plasma processing apparatus of appendix 3, wherein the controller decomposes the data obtained from the plurality of sensors into components of terms of the Zernike polynomials, and reconstructs each term of the Zernike polynomials with a component intensity of each decomposed term, thus obtaining the two-dimensional distribution.

(Appendix 5)

The plasma processing apparatus of appendix 3 or 4, wherein the controller detects an abnormality depending on whether the component intensity of each term of the decomposed Zernike polynomials is within a predetermined normal range.

(Appendix 6)

The plasma processing apparatus of any one of appendices 3 to 5, wherein the controller monitors the component intensity of each term of the decomposed Zernike polynomials during plasma processing, and detects whether the component intensity of any term has changed beyond an allowable value.

(Appendix 7)

The plasma processing apparatus of any one of appendices 3 to 6, wherein the controller performs machine learning on a data set in which a measurement result of the abnormality occurring during the plasma processing is associated with the component intensity of each term of the decomposed Zernike polynomials, and identifies the component intensity of the term of the Zernike polynomials that contributes highly to the abnormality.

(Appendix 8)

The plasma processing apparatus of any one of appendices 3 to 7, further comprising:
a storage part storing a first predictive model that learns a relationship between a processing result of the plasma processing and the component intensity of each term of the Zernike polynomials, and a second predictive model that learns a relationship between a processing condition of the plasma processing and the component intensity of each term of the Zernike polynomials,
wherein the controller predicts the component intensity of each term of the Zernike polynomials which results in a predetermined processing result on the substrate, by the first predictive model, and predicts the processing condition of the plasma processing in which the component intensity of each term of the Zernike polynomials becomes the predicted component intensity, by the second predictive model.

(Appendix 9)

The plasma processing apparatus of any one of appendices 1 to 8, wherein the controller estimates the state of plasma on the substrate, by solving a diffusion equation based on the obtained two-dimensional distribution.

(Appendix 10)

A plasma state estimation method for a plasma processing apparatus comprising a processing container in which a mounting table on which a substrate is mounted is arranged and plasma processing is performed, and a plurality of sensors for detecting a state of plasma generated in the processing container, the method comprising:
obtaining a two-dimensional distribution representing the state of plasma with respect to installation positions of the plurality of sensors, from data obtained from the plurality of sensors; and
estimating the state of plasma in the processing container based on the obtained two-dimensional distribution.

1. A plasma processing apparatus comprising:
a processing container in which a mounting table on which a substrate is mounted is arranged and plasma processing is performed;
a plurality of sensors for detecting a state of plasma generated in the processing container; and
a controller for estimating a state of plasma in the processing container based on the state of plasma obtained from the plurality of sensors,
wherein the controller obtains a two-dimensional distribution representing the state of plasma with respect to installation positions of the plurality of sensors, from data obtained from the plurality of sensors, and estimates the state of plasma in the processing container based on the obtained two-dimensional distribution.

2. The plasma processing apparatus of claim 1, wherein the controller obtains the two-dimensional distribution by interpolating a state between the installation positions of the plurality of sensors using an orthogonal function system, from the data obtained from the plurality of sensors.

3. The plasma processing apparatus of claim 2, wherein the orthogonal function system is Zernike polynomials.

4. The plasma processing apparatus of claim 3, wherein the controller decomposes the data obtained from the plurality of sensors into components of terms of the Zernike polynomials, and reconstructs each term of the Zernike polynomials with a component intensity of each decomposed term, thus obtaining the two-dimensional distribution.

5. The plasma processing apparatus of claim 3, wherein the controller detects an abnormality depending on whether the component intensity of each term of the decomposed Zernike polynomials is within a predetermined normal range.

6. The plasma processing apparatus of claim 4, wherein the controller monitors the component intensity of each term of the decomposed Zernike polynomials during plasma processing, and detects whether the component intensity of any term has changed beyond an allowable value.

7. The plasma processing apparatus of claim 4, wherein the controller performs machine learning on a data set in which a measurement result of the abnormality occurring during the plasma processing is associated with the component intensity of each term of the decomposed Zernike polynomials, and identifies the component intensity of the term of the Zernike polynomials that contributes highly to the abnormality.

8. The plasma processing apparatus of claim 4, further comprising:
a storage part storing a first predictive model that learns a relationship between a processing result of the plasma processing and the component intensity of each term of the Zernike polynomials, and a second predictive model that learns a relationship between a processing condition of the plasma processing and the component intensity of each term of the Zernike polynomials,
wherein the controller predicts the component intensity of each term of the Zernike polynomials which results in a predetermined processing result on the substrate, by the first predictive model, and predicts the processing condition of the plasma processing in which the component intensity of each term of the Zernike polynomials becomes the predicted component intensity, by the second predictive model.

9. The plasma processing apparatus of claim 1, wherein the controller estimates the state of plasma on the substrate, by solving a diffusion equation based on the obtained two-dimensional distribution.

10. A plasma state estimation method for a plasma processing apparatus comprising a processing container in which a mounting table on which a substrate is mounted is arranged and plasma processing is performed, and a plurality of sensors for detecting a state of plasma generated in the processing container, the method comprising:
obtaining a two-dimensional distribution representing the state of plasma with respect to installation positions of the plurality of sensors, from data obtained from the plurality of sensors; and
estimating the state of plasma in the processing container based on the obtained two-dimensional distribution.
